(19) United States
(12) Patent Application Publication
(10) Pub. No.: US 2013/0181349 A1
(43) Pub. Date: Jul. 18, 2013

(54) SEMICONDUCTOR DEVICE HAVING THROUGH-SUBSTRATE VIA

(71) Applicants: Chie KOYAMA, Kanagawa-ken (JP); Satoyuki Miyako, Kanagawa-ken (JP); Eiji Sato, Kanagawa-ken (JP)

(72) Inventors: Chie KOYAMA, Kanagawa-ken (JP); Satoyuki Miyako, Kanagawa-ken (JP); Eiji Sato, Kanagawa-ken (JP)

(73) Assignee: Kabushiki Kaisha Toshiba, Tokyo (JP)

(21) Appl. No.: 13/599,041

(22) Filed: Aug. 30, 2012

(30) Foreign Application Priority Data
Jan. 12, 2012 (JP) 2012-004041

(51) Int. Cl. H01L 23/498

(52) U.S. Cl. 257/741; 257/774; 257/E23.067

(57) ABSTRACT

According to an embodiment, a semiconductor device includes a first circuit block, a first through-substrate via, and a back surface wiring. The first circuit block is provided on a surface side of a semiconductor substrate. The first through-substrate via is provided along a circumference of the first circuit block so as to separate the first circuit block from other circuit blocks. The first circuit block is provided so as to penetrate the surface of the semiconductor substrate. The first circuit block is isolated from the surroundings. The first circuit block has conductivity. The back surface wiring is provided on the back surface side of the semiconductor substrate. The back surface wiring is connected to the first through-substrate via. The back surface wiring connects the first through-substrate via to a power supply terminal or a shield potential terminal.

### CROSS REFERENCE TO RELATED APPLICATION

This application is based upon and claims the benefit of priority from the prior Japanese Patent Application No. 2012-004041, filed on Jan. 12, 2012, the entire contents of which are incorporated herein by reference.

### FIELD

Embodiments described herein relate to a semiconductor device having a through-substrate via.

### BACKGROUND

In a solid-state imaging device such as a CMOS image sensor, it is necessary to prevent noise from mixing into a sensor circuit unit from a peripheral circuit unit. Accordingly, in order to prevent noise being mixed from the surroundings, deep trench isolation is arranged on a circumference of the sensor circuit unit or the peripheral circuit unit that is a factor of noise occurrence. The deep trench isolation is used in a floating state in which electrical connection has not been made or in a potential-fixed state using surface wiring provided on the surface side of a silicon substrate.

In the case where the deep trench isolation is floating, the noise interception capability becomes weak. Further, in the case of fixing the potential of the deep trench isolation using the surface wiring, there is a problem that the wiring region on the surface side of the silicon substrate is decreased depending on the surface wiring.

### BRIEF DESCRIPTION OF THE DRAWINGS

FIGS. 1A and 1B are a plan view and a cross-sectional view illustrating the schematic structure of a semiconductor device according to a first embodiment;

FIGS. 2A and 2B are a plan view and a cross-sectional view illustrating the schematic structure of a semiconductor device according to a second embodiment;

FIGS. 3A to 3C are plan views illustrating the schematic structure of a semiconductor device according to a third embodiment;

FIGS. 4A to 4D are plan views illustrating the schematic structure of a semiconductor device according to a fourth embodiment;

FIGS. 5A and 5B are a plan view and a cross-sectional view illustrating the schematic structure of a semiconductor device according to a fifth embodiment;

FIG. 6 is a cross-sectional view illustrating a relationship between a sensor unit and a terminal unit of a semiconductor device of FIGS. 5A and 5B;

FIG. 7 is a cross-sectional view illustrating a relationship between a sensor unit and a terminal unit of a semiconductor device of FIGS. 5A and 5B;

FIG. 8 is a plan view illustrating the overall configuration of a semiconductor device according to a fifth embodiment; and

FIG. 9 is an enlarged view of terminals in an I/O block of the semiconductor device of FIG. 8.

### DETAILED DESCRIPTION

According to one embodiment, a semiconductor device includes a first circuit block, a first through-substrate via, and a back surface wiring. The first circuit block is provided on a surface side of a semiconductor substrate. The first through-substrate via is provided along a circumference of the first circuit block so as to separate the first circuit block from other circuit blocks. The first circuit block is provided so as to penetrate the surface of the semiconductor substrate. The first circuit block is isolated from the surroundings. The first circuit block has conductivity. The back surface wiring is provided on the back surface side of the semiconductor substrate. The back surface wiring is connected to the first through-substrate via. The back surface wiring connects the first through-substrate via to a power supply terminal or a shield potential terminal.

Hereinafter, a plurality of further embodiments will be described with reference to the drawings. In the drawings, the same reference numerals denote the same or similar portions.

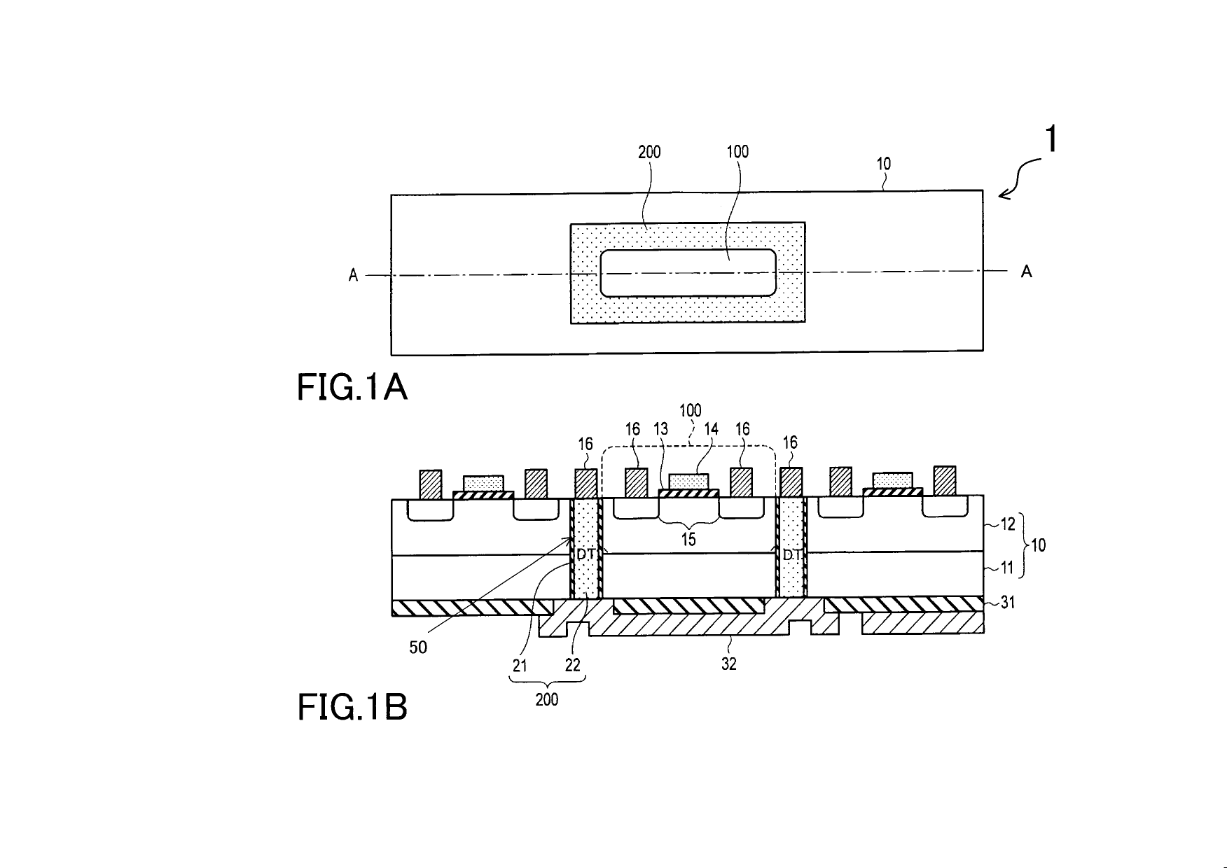

A semiconductor device according to the first embodiment will be described with reference to FIGS. 1A and 1B. FIGS. 1A and 1B are views illustrating the schematic structure of a semiconductor device. FIG. 1A is a plan view, and FIG. 1B is a cross-sectional view taken along line A-A of FIG. 1A.

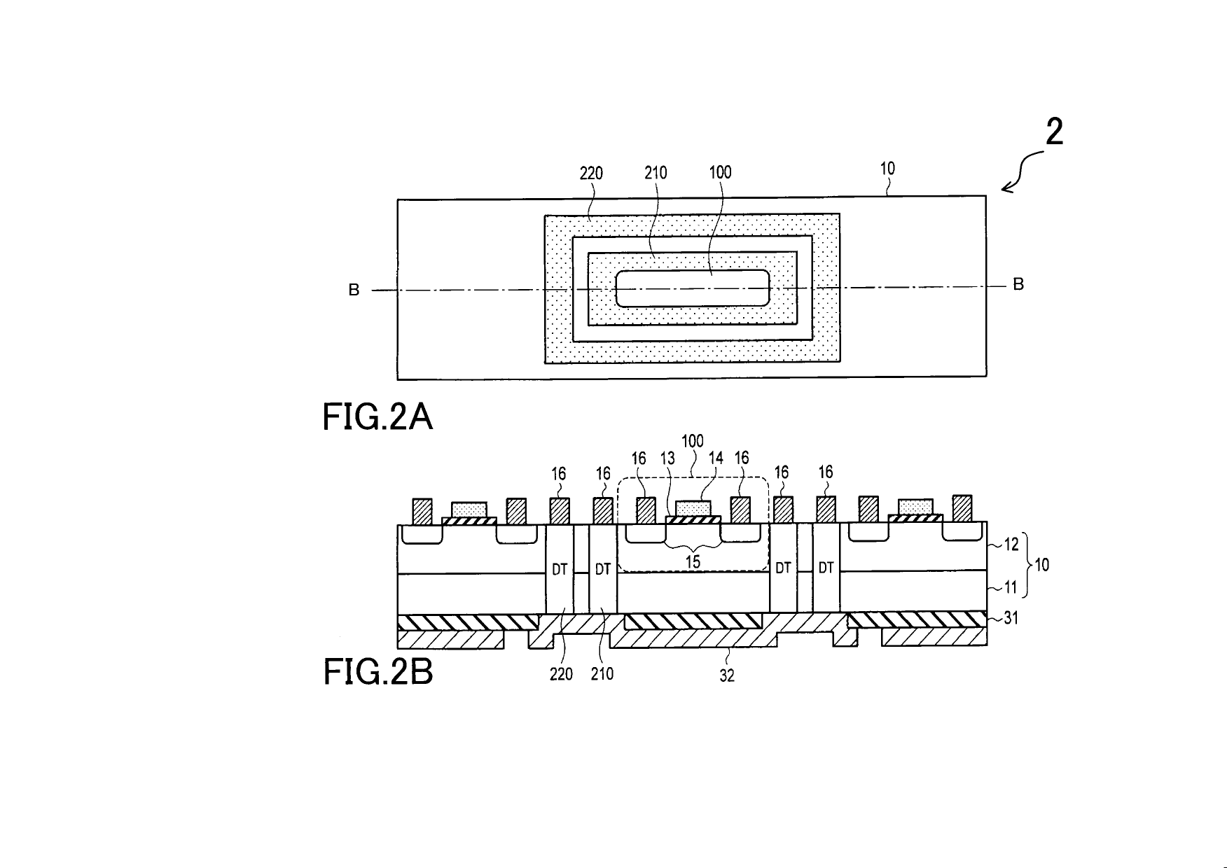

As illustrated in FIGS. 1A and 1B, a semiconductor device 1 includes a first circuit block 100, and a through-substrate via 200. A substrate 10 is a semiconductor substrate in which a well region 12 is formed on a silicon substrate 11. On a surface side of the substrate 10, the first circuit block 100 having a MOS transistor and the like is formed. On a peripheral portion of the first circuit block 100, other circuit blocks (not illustrated, second, third, . . . , and n-th circuit blocks) are formed. The first circuit block 100 is surrounded by a through-substrate via 200 that is provided so as to penetrate through the substrate 10, and is separated from other circuit blocks. In the case of a silicon substrate, the first circuit block 100 is also called a through-silicon via. In the drawing, the through-substrate via is denoted by DT (Deep Trench) (in FIGS. 2A to 7 and FIG. 9, the through-substrate via is denoted by DT (Deep Trench) in the same manner). On the through-substrate via 200, a silicon oxide film 21 that is a dielectric layer is formed on a side surface of a via hole 50 that is provided so as to penetrate through the substrate 10. A conductive polycrystalline silicon film 22, which is a conductive material, is buried in the via hole 50 through the silicon oxide film 21. Since the through-substrate via 200 is formed to surround the first circuit block 100, the through-substrate via 200 functions as so-called deep trench isolation for element isolation. Here, a silicon oxide film is used as the dielectric layer. Although an N-type polycrystalline silicon film is used as the conductive material, a P-type polycrystalline silicon film may be used instead. For example, in the case where a polycrystalline silicon film doped with high-concentration N-type or P-type impurities is used, the resistance of the through-substrate via can be greatly reduced.

On the back surface side of the substrate 10, an insulating film 31 such as a silicon oxide film or the like is formed. An opening is provided in a portion that is positioned on a lower surface of the through-substrate via 200 on the insulating film 31. A back surface wiring 32 is formed on the insulating film 31, and the back surface wiring 32 is electrically connected to the lower surface of the through-substrate via 200 in the opening of the insulating film 31. The back surface wiring 32 is connected to a power supply terminal or a shield potential terminal (not illustrated). Here, although the power supply terminal or the shield potential terminal is provided on the back surface side so as not to shrink the wiring region on the surface side, the power supply terminal or the shield potential terminal may be provided on the surface side. That is, the through-substrate via 200 according to the embodiment, unlike the deep trench isolation in the related art, reaches from the surface of the substrate 10 to the back surface of the substrate 10, and is set to a predetermined potential using the back surface wiring 32.

On a gate insulating film 13, a gate electrode 14 is provided. Each contact 16 is provided on a source/drain region 15, on the surface side of the conductive polycrystalline silicon film 22 of the through-substrate via 200. Each contact 16 is connected to a wiring on the substrate surface side (not illustrated). Since the through-substrate via 200 is connected to the back surface wiring 32, it is possible to connect the back surface wiring 32 to the wiring on the surface side through the through-substrate via 200.

According to the embodiment, since the through-substrate via 200 is provided so as to surround the periphery of the first circuit block 100, the first circuit block 100 can be separated from other circuit blocks, and the through-substrate via 200 is efficient to suppress noise between circuits. By fixing the potential of the through-substrate via 200, high noise suppressing effect can be obtained. Since the through-substrate via 200 is connected to the back surface wiring 32, the terminal and the through-substrate via can be connected to each other without reducing wiring resources of a circuit formed on the surface side of the substrate 10.

In the embodiment, since the through-substrate via 200 is connected to, for example, the power supply terminal on the back surface side, not only the noise suppression but also power reinforcement of the silicon surface circuit can be performed, and thus the reduction of an IR drop and the increase of the surface wiring region can be expected.

In a semiconductor device having a wiring provided on the back surface side of the substrate, the through-substrate via is provided in the circuit region. It is preferable that the through-substrate via 200 is formed simultaneously with the through-substrate via in the circuit region. In such a semiconductor device, a new process is not necessary to form the through-substrate via 200. Accordingly, the through-substrate via 200 can be formed without causing the increase of the manufacturing cost, and thus usefulness is improved.

A semiconductor device according to a second embodiment will be described with reference to FIGS. 2A and 2B. FIGS. 2A and 2B are views illustrating the schematic structure of a semiconductor device. FIG. 2A is a plan view, and FIG. 2B is a cross-sectional view taken along line B-B of FIG. 2A.

Hereinafter, the same reference numerals are given to the same configuration portions as the first embodiment. The description of the same portions will be omitted, but only the different portions will be described.

As illustrated in FIGS. 2A and 2B, in a semiconductor device 2 according to the embodiment, the through-substrate is doubly provided. That is, the periphery of a first circuit block 100 is surrounded by a first through-substrate via 210. The periphery of the first through-substrate via 210 is surrounded by the second through-substrate via 220 that is arranged to be spaced apart from the first through-substrate via 210. In the same manner as the through-substrate via 200 according to the first embodiment, the through-substrate via 210 and the through-substrate via 220 are composed of the silicon oxide film 21 that is the dielectric layer and the polycrystalline silicon film 22 that is the conductive material, and is provided so as to penetrate the surface of the substrate 10. Other circuit blocks (not illustrated) are formed on the outside of the through-substrate via 220.

The first through-substrate via 210 and the second through-substrate via 220 are electrically connected to the back surface wiring 32 on the back surface side, respectively, and are connected to a power supply terminal or a shield potential terminal (not illustrated). The first through-substrate via 210 and the second through-substrate via 220 are not necessarily connected to the same back surface wiring 32, but may be connected to other back surface wirings.

As described above, according to the semiconductor device of the embodiment, the same effect as the first embodiment is obtained. The noise suppressing effect can be obtained through one kind of through-substrate via. However, in the case of two kinds of through-substrate via, since the through-substrate via 210 and the through-substrate via 220 are electrically fixed, the resistance of the through-substrate via can be reduced, and thus twice or more effect can be obtained in comparison to the one kind of through-substrate via. In comparison to the case in the related art in which protection against noise is performed depending on deep-n well/deep-p well, the number of processes can be reduced through the semiconductor device 2 according to the embodiment.

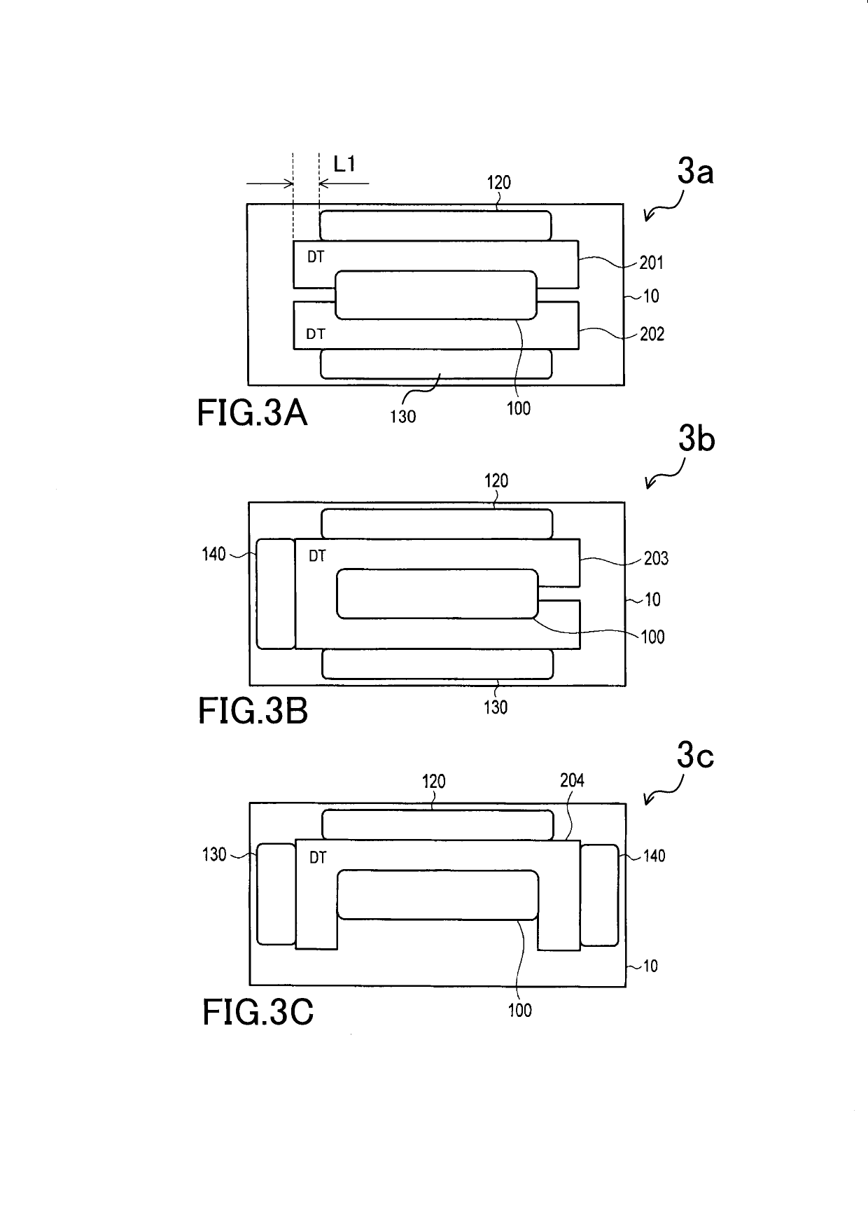

A semiconductor device according to a third embodiment will be described with reference to FIGS. 3A to 3C. FIGS. 3A to 3C are views illustrating the schematic structure of a semiconductor device.

Hereinafter, the same reference numerals are given to the same configuration portions as the first embodiment. The description of the same portions will be omitted, but only the different portions will be described.

The embodiment is different from the first embodiment on the point that the through-substrate via does not completely surround the first circuit block 100, but surrounds a part of the first circuit block 100.

As shown in FIG. 3A, a semiconductor device 3a includes a first circuit block 100, a second circuit block 120, a third circuit block 130, a through-substrate via 201, and a through-substrate via 202. The first circuit block 100 is interposed between the through-substrate vias 201, 202 with a horseshoe shape, which are provided both sides, that is, upper and lower sides, of the first circuit block 100. End portions of the through-substrate via 201 and the through-substrate via 202 are extended than an end portion of the circuit block. For example, the through-substrate via 201 is extended as long as a distance L1 than the second circuit block 120. As a result, the first circuit block 100 and the second circuit block 120 on the upper side are separated from each other by the through-substrate via 201, and the first circuit block 100 and the third circuit block 130 on the lower side are separated from each other by the through-substrate via 202.

As shown in FIG. 3B, a semiconductor device 3b includes a first circuit block 100, a second circuit block 120, a third circuit block 130, a fourth circuit block 140, and a through-substrate via 203. The first circuit block 100 is surrounded by the C-shaped through-substrate via 203. As a result, the first circuit block 100 and the second circuit block 120 (upper side), the first circuit block 100 and the third circuit block 130 (lower side), and the first circuit block 100 and the fourth circuit block 140 (left side) are respectively separated from each other by the through-substrate via 203.

As shown in FIG. 3C, a semiconductor device 3c includes a first circuit block 100, a second circuit block 120, a third circuit block 130, a fourth circuit block 140, and a through-substrate via 204. The first circuit block 100 is interposed between the through-substrate vias 204 with a horseshoe shape, which are provided the upper side of the first circuit block 100. As a result, the first circuit block 100 and the second circuit block 120 (upper side), the first circuit block 100 and the third circuit block 130 (left side), and the first circuit block 100 and the fourth circuit block 140 (right side) are respectively separated from each other by the through-substrate via 204.

Although not illustrated, the through-substrate vias 201 to 204, in the same manner as the through-substrate via 200 according to the first embodiment, are composed of the silicon oxide film 21 that is the dielectric layer and the polycrystalline silicon film 22 that is the conductive material, and is provided so as to penetrate through the substrate 10. A wiring is connected to the back surface side of the substrate 10, and through the back surface wiring, the through-substrate vias 201 to 204 are connected to the power supply terminal or the shield potential terminal.

As described above, in the semiconductor device according to the embodiment, the first circuit block 100 can be sufficiently separated from the second to fourth circuit blocks 120, 130, 140, and thus the same effect as the first embodiment is obtained.

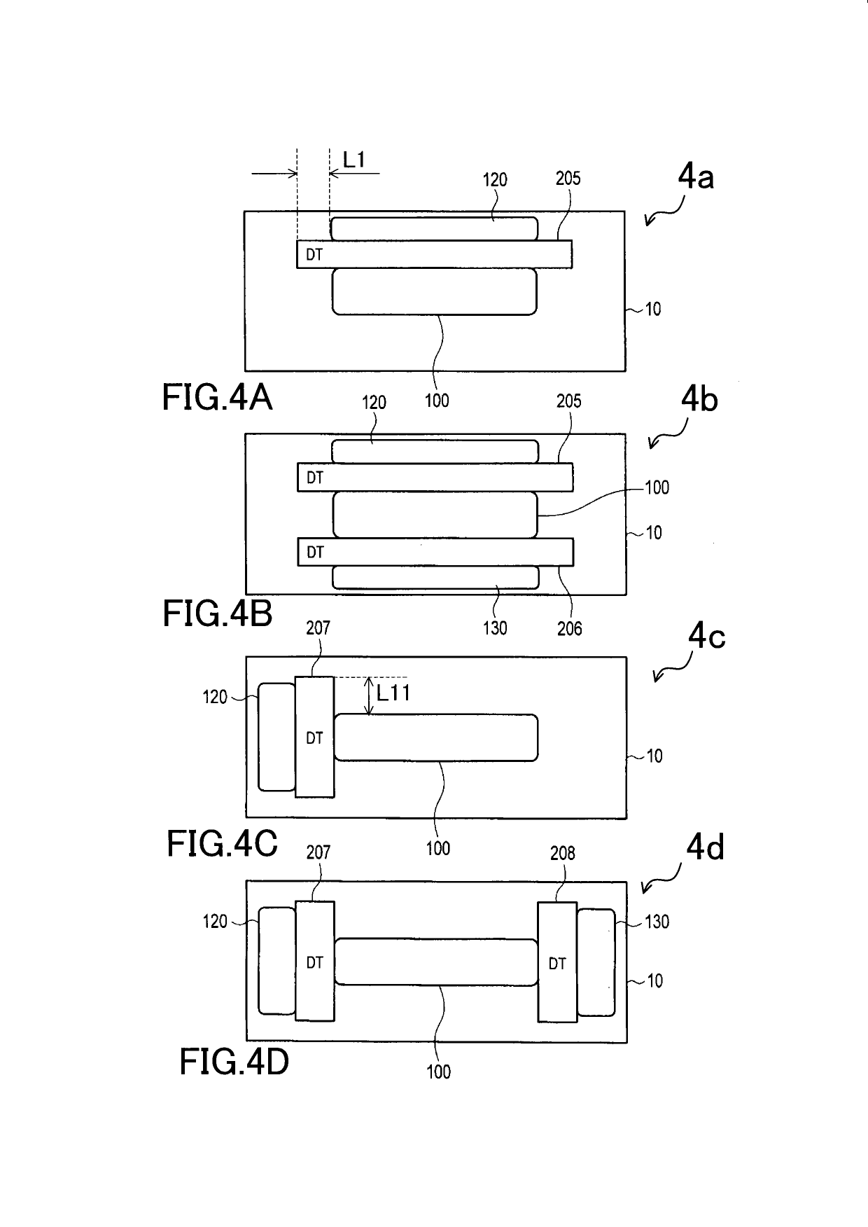

A semiconductor device according to a fourth embodiment will be described with reference to FIGS. 4A to 4D. FIGS. 4A to 4D are views illustrating the schematic structure of a semiconductor device. Hereinafter, the same reference numerals are given to the same configuration portions as the first embodiment. The description of the same portions will be omitted, but only the different portions will be described.

The embodiment is different from the first embodiment on the point that the through-substrate via does not completely surround the first circuit block 100, but surrounds a part of the first circuit block 100.

As shown in FIG. 4A, a semiconductor device 4a includes a first circuit block 100, a second circuit block 120, and a through-substrate via 205. The through-substrate via 205 with a rectangular shape, in which a horizontal side is longer than a vertical side, is arranged on an upper side of the first circuit block 100, and the first circuit block 100 and the second circuit block 120 are separated from each other. An end portion of the through-substrate via 205 is extended than an end portion of the circuit block. For example, the through-substrate via 205 is extended as long as a distance L1 than the second circuit block 120. As a result, the first circuit block 100 and the second circuit block 120 on the upper side are separated from each other by the through-substrate via 205.

As shown in FIG. 4B, a semiconductor device 4b includes a first circuit block 100, a second circuit block 120, a third circuit block 130, a through-substrate via 205, and a through-substrate via 206. The first circuit block 100 is interposed between the through-substrate via 205 with a rectangular shape in which the horizontal side is longer than the vertical side and the through-substrate via 206, which are provided both sides, that is, upper and lower sides, of the first circuit block 100. As a result, the first circuit block 100 and the second circuit block 120 on the upper side are separated from each other by the through-substrate via 205, and the first circuit block 100 and the third circuit block 130 on the lower side are separated from each other by the through-substrate via 206.

As shown in FIG. 4C, a semiconductor device 4c includes a first circuit block 100, a second circuit block 120, and a through-substrate via 207. On the left side of the first circuit block 100, the through-substrate via 207 with a rectangular shape, in which the vertical side is longer than the horizontal side, is arranged, and on the right side of the through-substrate via 207, the second circuit block 120 with a rectangular shape, in which the vertical side is longer than the horizontal side, is arranged. The through-substrate via 207, for example, is extended as long as a distance L11 in the vertical direction than the first circuit block 100. As a result, the first circuit block 100 and the second circuit block 120 are separated from each other by the through-substrate via 207.

As shown in FIG. 4D, a semiconductor device 4d includes a first circuit block 100, a second circuit block 120, a third circuit block 130, a through-substrate via 207, and a through-substrate via 208. The first circuit block 100 is interposed between the through-substrate via 207 with a rectangular shape, in which the vertical side is longer than the horizontal side, and the through-substrate via 208, which are provided both sides, that is, left and right sides, of the first circuit block 100. As a result, the first circuit block 100 and the second circuit block 120 on the left side are separated from each other by the through-substrate via 207, and the first circuit block 100 and the third circuit block 130 on the right side are separated from each other by the through-substrate via 208.

Although not illustrated, the through-substrate vias 205 to 208, in the same manner as the through-substrate via 200 according to the first embodiment, are composed of the silicon oxide film 21 that is the dielectric layer and the polycrystalline silicon film 22 that is the conductive material, and are provided so as to penetrate through the substrate 10. A wiring is connected to the back surface side of the substrate 10, and through the back surface wiring, the through-substrate vias 205 to 208 are connected to the power supply terminal or the shield potential terminal. In order to clearly separate the first circuit block 100 from other circuit blocks, it is preferable that the through-substrate vias 205 to 208 be longer than a length of a side that faces the first circuit block 100.

As described above, in the semiconductor device according to the embodiment, since the through-substrate vias 205 to 208 are arranged only in portions in which the separation is necessary, the first circuit block 100 can be sufficiently separated from the second to fourth circuit blocks 120, 130, 140, and thus the same effect as the first embodiment is obtained.

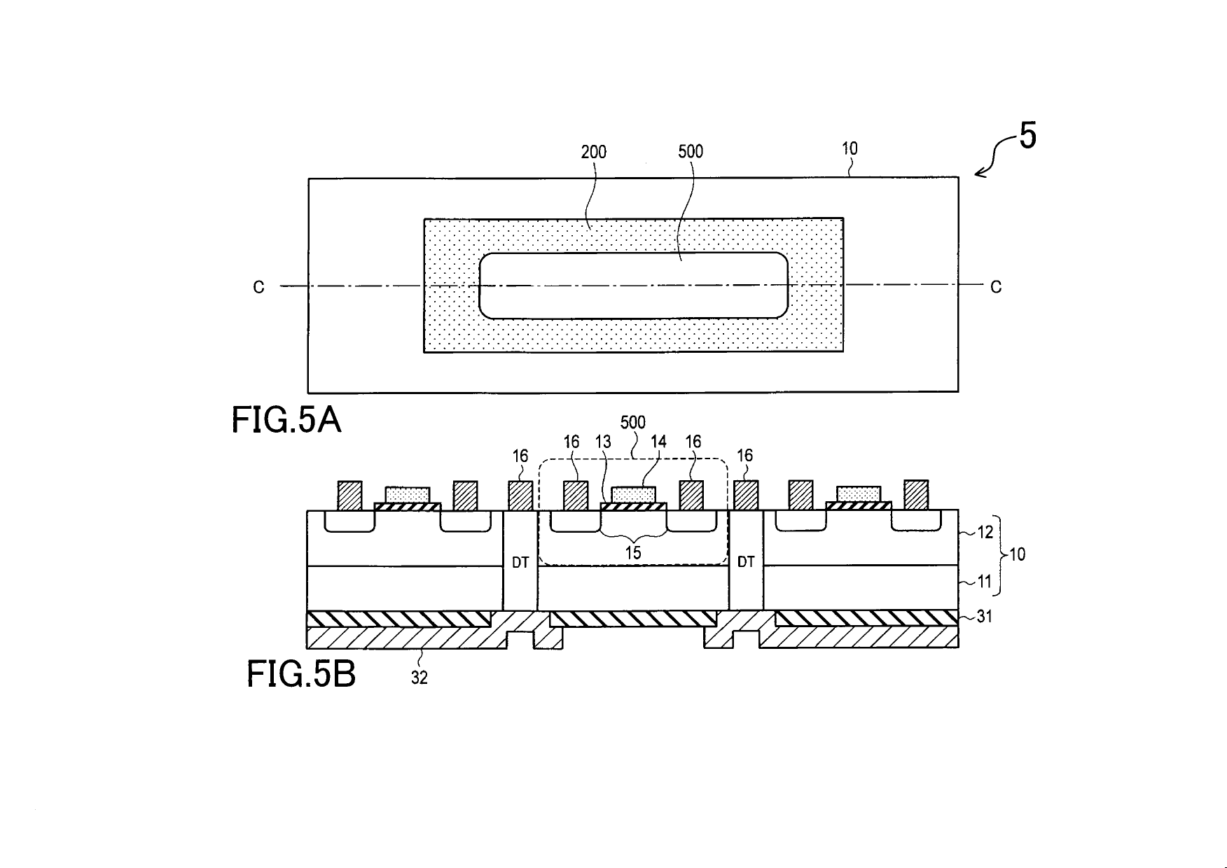

A semiconductor device according to a fifth embodiment will be described with reference to FIGS. 5A and 5B. FIG. 5A is a plan view illustrating the schematic structure of a semiconductor device, and FIG. 5B is a cross-sectional view taken along line C-C of FIG. 5A. Hereinafter, the same reference numerals are given to the same configuration portions as the first embodiment, and the description of the portions will be omitted, but only different portions will be described.

The embodiment is an example that is applied to a back surface irradiation type CMOS image sensor, and has the same basic configuration as the first embodiment.

As illustrated in FIGS. 5A and 5B, a semiconductor device 5 includes a pixel circuit block (first circuit block) 500 and a through-substrate via 200. The pixel circuit block 500 has a MOS transistor and the like that forms a pixel portion of a CMOS image sensor, and is formed on the surface side of the substrate 10. On the peripheral portion of the pixel circuit block 500, other peripheral circuit block is formed. The periphery of the pixel circuit block 500 is surrounded by the through-substrate via 200 that is provided so as to penetrate through the substrate 10, and is separated from other peripheral circuit blocks.

On the back surface side of the substrate 10, an insulating film 31 such as a silicon oxide film or the like is formed, and an opening is provided in a portion that is positioned on a lower surface of the through-substrate via 200 on the insulating film 31. A back surface wiring 32 is formed on the insulating film 31, and the back surface wiring 32 is electrically connected to the lower surface of the through-substrate via 200 in the opening of the insulating film 31. The back surface wiring 32 is connected to a power supply terminal or a shield potential terminal (not illustrated).

In the case where the back surface wiring 32 exists in a path of light that is incident to the pixel circuit block 500, the incident light quantity is decreased or the picture quality is deteriorated. Accordingly, the back surface wiring 32 is formed to be arranged so as not to overlap the pixel circuit block 500.

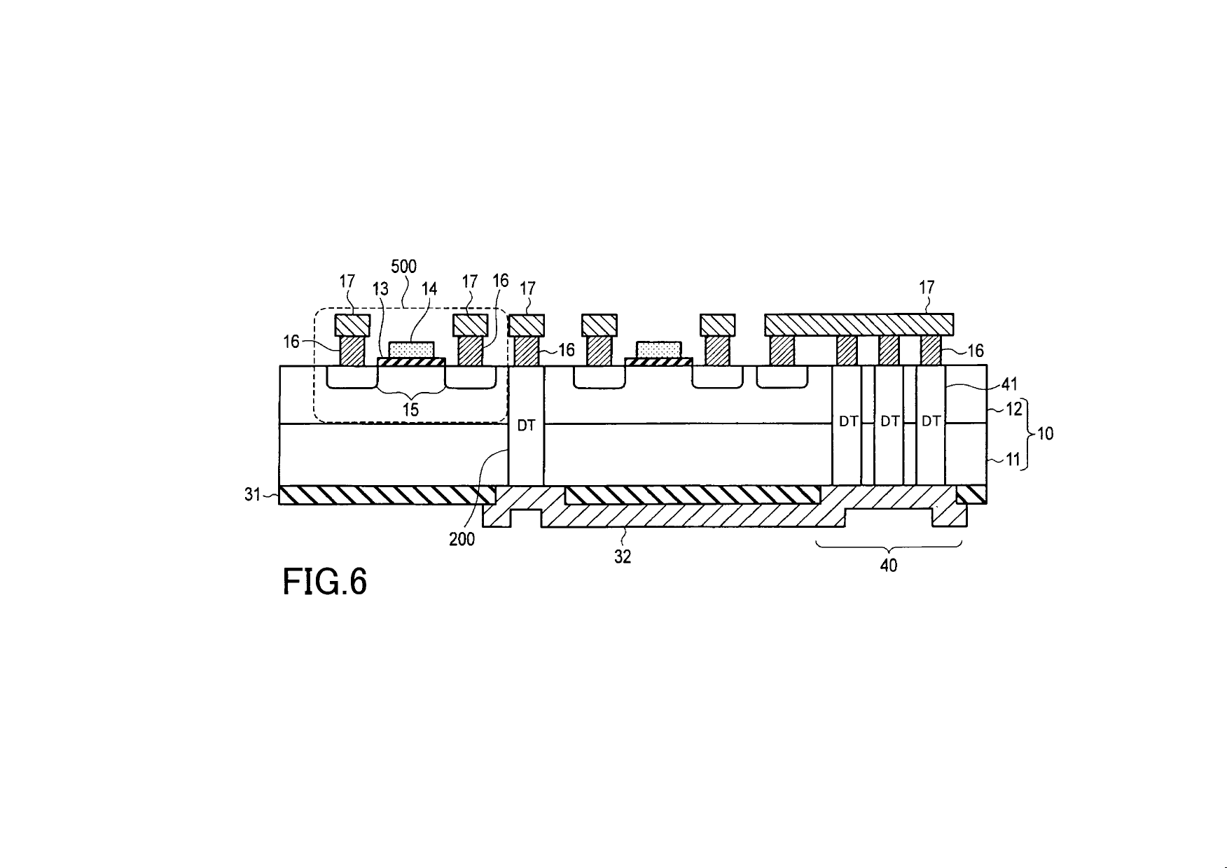

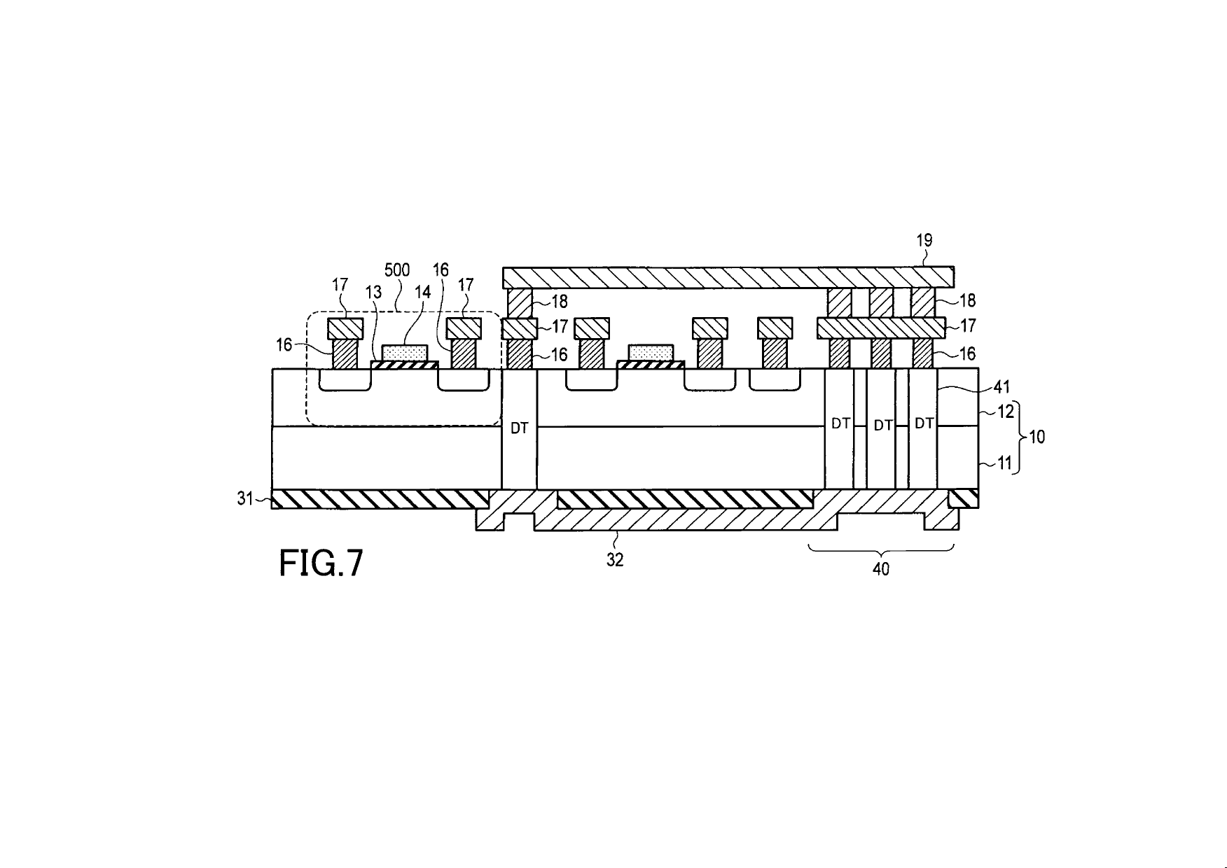

A relationship between a sensor unit using a CMOS image sensor and a terminal will be described with reference to FIGS. 6 and 7. FIGS. 6 and 7 are cross-sectional views illustrating a relationship between a sensor unit and a terminal unit of a semiconductor device.

As shown in FIG. 6, in a peripheral circuit, a plurality of through-substrate vias 41 that is connected to a terminal 40 on the back surface side is provided, and the terminal 40 on the back surface side and a surface wiring 17 are connected to each other by the plurality of through-substrate vias 41. That is, the through-substrate vias 41 are connected to the terminal 40 that is a part of the back surface wiring 32 provided on the back surface side of the substrate, and are connected to the surface wiring 17 through contacts 16 on the surface side of the substrate. FIG. 7 shows contacts 18 and surface wiring 19 on the further upper layer provided in addition to the configuration illustrated in FIG. 6.

By adding wiring onto the surface, the noise suppressing effect can be further heightened in comparison to the semiconductor device according to the first embodiment.

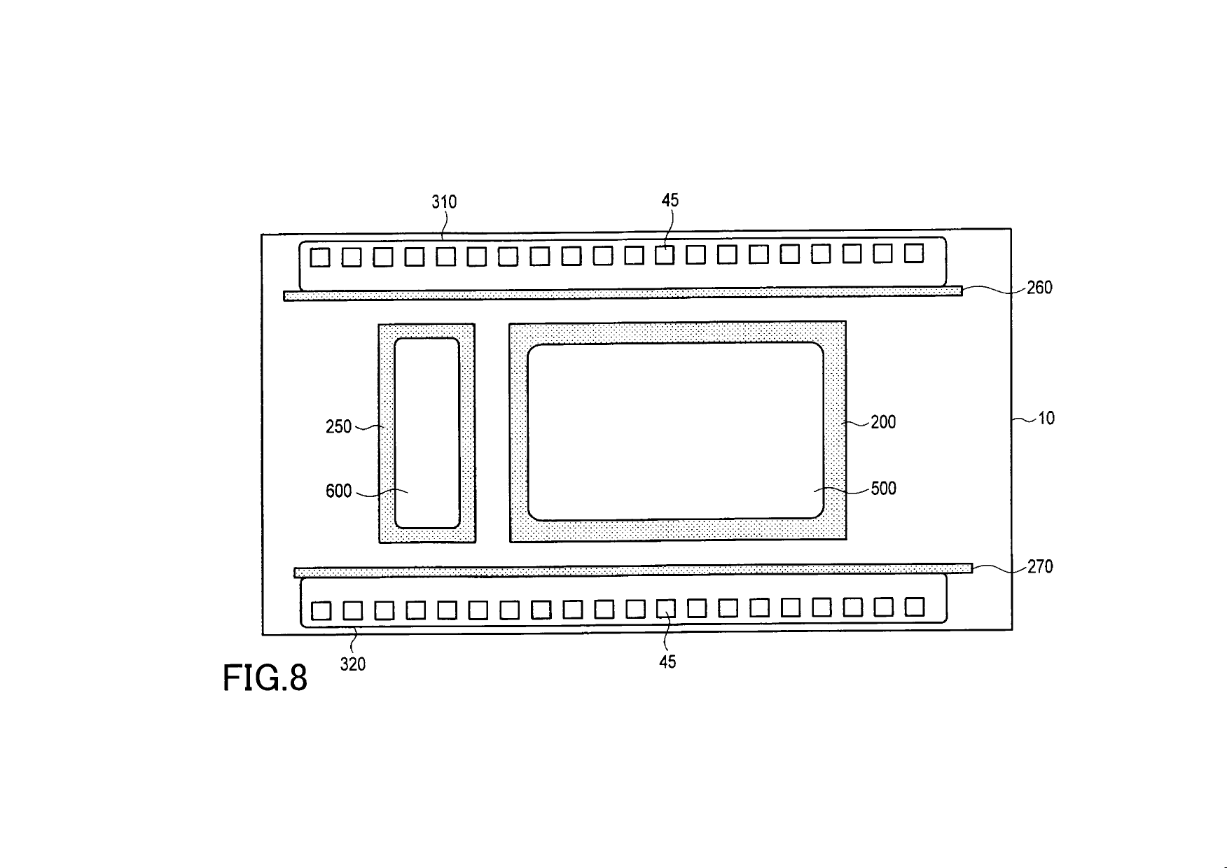

A semiconductor device including a terminal unit will be described with reference to FIG. 8. FIG. 8 is a plan view illustrating the overall configuration of a CMOS image sensor according to the embodiment.

As illustrated in FIG. 8, on the periphery of the pixel circuit block 500, for example, on the left side, an analog circuit block 600 is arranged. The pixel circuit block 500 is surrounded by the through-substrate via 200, and the analog circuit block 600 is surrounded by the through-substrate via 250.

On the peripheral portion of the substrate on an upper portion of the pixel circuit block 500, an I/O block 310 in which a plurality of terminals 45 is arranged is provided, and a through-substrate via 260 with a rectangular shape in which the horizontal side is longer than the vertical side is provided between the I/O block 310 and the pixel circuit block 500.

On the peripheral portion of the substrate on a lower portion of the pixel circuit block 500, an I/O block 320 in which a plurality of terminals 45 is arranged is provided, and a through-substrate via 270 with a rectangular shape in which the horizontal side is longer than the vertical side is provided between the I/O block 320 and the pixel circuit block 500.

Although not illustrated, the through-substrate vias 200, 250, 260, 270, in the same manner as the first embodiment, are composed of the silicon oxide film 21 that is the dielectric layer and the polycrystalline silicon film 22 that is the conductive material, and are provided so as to penetrate through the substrate 10. The through-substrate vias 200, 250, 260, 270 are connected to the wiring on the back surface side of the substrate 10, and are connected to the power supply terminal or the shield potential terminal.

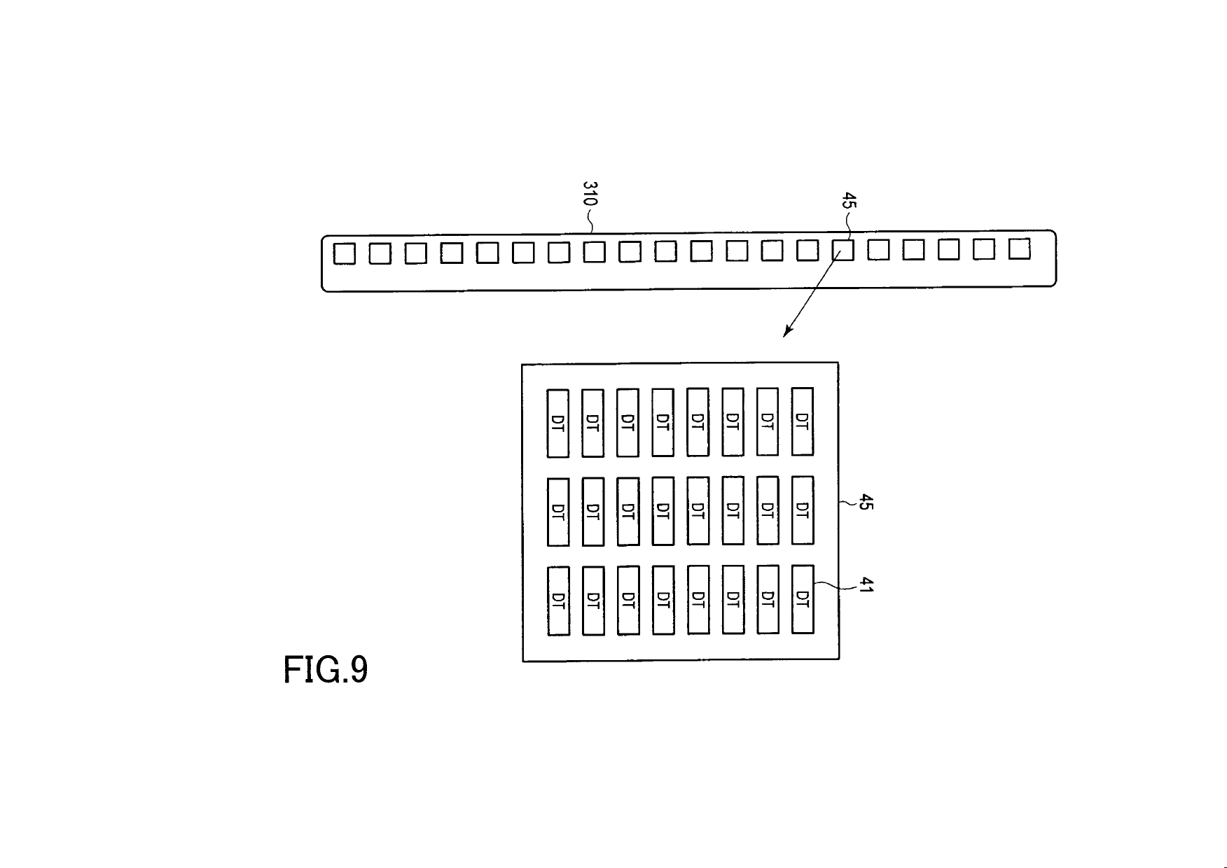

The terminals in the I/O block of the semiconductor device will be described with reference to FIG. 9. FIG. 9 is an enlarged view of the terminals 45 in the I/O block 310 of the CMOS image sensor according to the embodiment. As shown in FIG. 9, a plurality of through-substrate vias 41 is provided in each terminal 45, and the terminal 45 is connected to the wiring on the back surface side through the plurality of through-substrate vias 41. In the terminal 45, for example, 24 (=3×8) through-substrate vias 41 are provided.

As described above, in the semiconductor device according to the embodiment, noise from the analog circuit block 600 to the pixel circuit block 500 in the CMOS image sensor can be suppressed, and the picture quality of the CMOS image sensor can be improved.

Further, in the embodiment, since the periphery of the pixel circuit block 500 is surrounded by the through-substrate vias 200, invasion of light from the surroundings to the pixel circuit block 500 can be prevented by the through-substrate vias 200 with an opaque material. Since the through-substrate vias 200 around the pixel circuit block 500 can be formed simultaneously with the through-substrate vias 41 connected to the terminals 45, a new process to form the through-substrate vias 200 is not necessary. The through-substrate vias 250, 260, 270 are the same. Accordingly, the increase of the manufacturing cost due to the forming of the through-substrate vias 200, 250, 260, 270 can be suppressed.

The invention is not limited to the above-described embodiments.

The through-substrate via may be formed to surround a part of the third circuit block as in the third embodiment, without the necessity of being formed to surround the overall of the first circuit block as in the first, second, and fifth embodiments. Further, as in the fourth embodiment, the through-substrate vias may be formed in a straight line between the adjacent circuit blocks. That is, it is sufficient that the through-substrate vias are provided between the circuit blocks that require noise suppression between the circuit blocks along the circumference of the first circuit block.

Although the conductive polycrystalline silicon film is used as the conductive material provided on the through-substrate vias, a conductive amorphous silicon film, a silicide film, a polycide film, Cu (Copper), Al (Aluminum), or the like may be used instead. Although the silicon oxide film is used as the dielectric layer provided on the through-substrate vias, a silicon nitride film or an insulating organic film may be used instead. Further, the application of the invention is not limited to a CMOS image sensor, but the invention can be applied to various kinds of semiconductor devices having circuit blocks that can maximally avoid the noise mixing from the surroundings.

While certain embodiments have been described, these embodiments have been presented by way of example only, and are not intend to limit the scope of the inventions. Indeed, the novel embodiments described herein may be embodied in a variety of the other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first circuit block provided on a surface side of a semiconductor substrate;
a first through-substrate via provided along a circumference of the first circuit block so as to separate the first circuit block from other circuit blocks, the first through-substrate via being provided so as to penetrate through the semiconductor substrate, the first through-substrate via being isolated from the surroundings, the first through-substrate via having conductivity; and
a back surface wiring provided on a back surface side of the semiconductor substrate, the back surface wiring being connected to the first through-substrate via, the back surface wiring to connect the first through-substrate via to a power supply terminal or a shield potential terminal.

2. The semiconductor device according to claim 1, further comprising
a second through-substrate via provided along a circumference of the first through-substrate via, the second through-substrate via being arranged to be spaced apart from the first through-substrate via, the second through-substrate via being provided so as to penetrate through the semiconductor substrate, the second through-substrate via being isolated from the surroundings, the second through-substrate via being connected to the back surface wiring, the second through-substrate via having conductivity.

3. The semiconductor device according to claim 1, wherein the first through-substrate via is arranged in a ring shape to surround an overall periphery of the first circuit block.

4. The semiconductor device according to claim 3, wherein the second through-substrate via is arranged in a ring shape to surround an overall periphery of the first through-substrate via.

5. The semiconductor device according to claim 1, wherein the first through-substrate via is arranged in a horseshoe shape to surround a part of the circumference of the first circuit block or extends on one side of the first circuit block in a linear shape that is longer than the one side.

6. The semiconductor device according to claim 1, wherein the first circuit block is a pixel circuit block in a CMOS image sensor.

7. The semiconductor device according to claim 1, wherein a back surface power supply terminal provided on the back surface side is connected to the back surface wiring, and the back surface wiring is connected to a wiring provided on the surface side of the semiconductor substrate through the first through-substrate via.

8. The semiconductor device according to claim 1, further comprising:
an I/O block provided with a plurality of terminals; and
a third through-substrate via provided between the first through-substrate via and the I/O block, the third through-substrate via including an end portion that is arranged to extend further than an end portion of the I/O block, the third through-substrate via being provided so as to penetrate through the semiconductor substrate, the third through-substrate via having conductivity.

9. The semiconductor device according to claim 1, wherein the shield potential terminal is set to a predetermined shield potential.

10. The semiconductor device according to claim 1, wherein in the first through-substrate via, a dielectric layer is provided on a side surface of a via hole, and a conductive material is buried to cover the via hole through a dielectric layer.

11. The semiconductor device according to claim 10, wherein the dielectric layer is any one of a silicon oxide film, a silicon nitride film and an insulating organic film.

12. The semiconductor device according to claim 10, wherein the conductive material is any one of a conductive polycrystalline silicon film, a conductive amorphous silicon film, a silicide film, a polyside film, Cu (Copper) and Al (Aluminum).

13. A semiconductor device comprising:
a first circuit block provided on a surface side of a semiconductor substrate;
a second circuit block arranged to be spaced apart from the first circuit block and provided on the surface side of the semiconductor substrate;
a first through-substrate via provided between the first circuit block and the second circuit block to be in contact with the first and second circuit blocks, the first through-substrate via including an end portion which extends in a linear shape further than end portions of the first and second circuit blocks, the first through-substrate via being provided so as to penetrate through the semiconductor substrate, the first through-substrate via being isolated from the surroundings, the first through-substrate via having conductivity; and
a back surface wiring provided on a back surface side of the semiconductor substrate, the back surface wiring being connected to the first through-substrate via, the back surface wiring to connect the first through-substrate via to a power supply terminal or a shield potential terminal.

14. The semiconductor device according to claim 13, wherein the first and second circuit blocks are pixel circuit blocks in a CMOS image sensor.

15. The semiconductor device according to claim 13, wherein a back surface power supply terminal provided on the back surface side is connected to the back surface wiring, and the back surface wiring is connected to a wiring provided on the surface side of the semiconductor substrate through the first through-substrate via.

16. The semiconductor device according to claim 13, wherein the shield potential terminal is set to a predetermined shield potential.

17. The semiconductor device according to claim 13, wherein in the first through-substrate via, a dielectric layer is provided on a side surface of a via hole, and a conductive material is buried to cover the via hole through the dielectric layer.

18. The semiconductor device according to claim 17, wherein the dielectric layer is any one of a silicon oxide film, a silicon nitride film and an insulating organic film.

19. The semiconductor device according to claim 17, wherein the conductive material is any one of a conductive polycrystalline silicon film, a conductive amorphous silicon film, a silicide film, a polyside film, Cu (Copper) and Al (Aluminum).
